(19) United States
(12) Patent Application Publication
(10) Pub. No.: US 2021/0372582 A1
(43) Pub. Date: Dec. 2, 2021

(54) MATRIX LIGHT SOURCE HAVING AN ADJUSTABLE ARCHITECTURE

(71) Applicant: VALEO VISION, Bobigny - Cedex (FR)

(72) Inventors: Samuel DAROUSSIN, Bobigny Cedex (FR); Alexandre VAL, Bobigny Cedex (FR); Zdravko ZOJCESKI, Bobigny Cedex (FR)

(73) Assignee: VALEO VISION, Bobigny - Cedex (FR)

(21) Appl. No.: 17/285,376

(22) PCT Filed: Oct. 10, 2019
(86) PCT No.: PCT/EP2019/077502

§ 371 Date: Apr. 14, 2021

(30) Foreign Application Priority Data
Oct. 15, 2018 (FR) 1859542

(51) Int. Cl. F21S 41/153; F21V 23/00

(52) U.S. Cl. CPC F21S 41/153; F21V 29/508; F21V 23/004

(57) ABSTRACT

The invention relates to a matrix light source having a plurality of elementary light sources with a light-emitting semiconductor element and an integrated circuit which includes the control logic pertaining to the elementary light sources of the matrix. The architecture of the light source is adjustable in that during production the size of the integrated circuit can be adapted to house matrices of different sizes using a repeatable structure.

The invention relates to electroluminescent semiconductor element-based matrix light sources, in particular for motor vehicles. The invention relates in particular to an adjustable architecture of matrix light sources.

A light-emitting diode (LED) is a semiconductor electronic component capable of emitting light when an electric current flows therethrough. In the automotive field, LED technology is increasingly being used for numerous light signaling solutions. LEDs are used to provide lighting functions such as daytime running lights, signaling lights, etc. The brightness emitted by an LED is generally dependent on the intensity of the electric current flowing therethrough. Inter alia, an LED is characterized by an electric current intensity threshold value. This maximum forward current generally decreases with increasing temperature. Likewise, when an LED emits light, a voltage drop equal to its forward voltage or nominal voltage is observed across its terminals.

The use of matrix arrays of LEDs comprising a high number of elementary electroluminescent light sources is beneficial in numerous fields of application, and in particular also in the field of lighting and signaling for motor vehicles. A matrix array of LEDs may be used for example to create light beam forms that are beneficial for lighting functions, such as headlights/road lighting or daytime running lights. In addition, a plurality of different lighting functions may be produced using a single matrix array, thus reducing the physical bulk in the restricted space of a motor vehicle light.

As is known, matrix light sources or, equivalently, pixelated light sources are controlled by a control unit that is physically remote from and electrically connected to the light source. It has been proposed to integrate at least some of the electronic circuits required for driving a light source into an ASIC (“application-specific integrated circuit”) integrated circuit on which a matrix array of light sources is placed. However, depending on the size of the matrix array of light sources, known integrated circuits have to be redeveloped for each application. Moreover, the production yield of matrix arrays of semiconductor element-based elementary light sources having homogeneous characteristics remains limited. It is difficult in particular to harness the production of large-scale matrix arrays that would still allow more diverse applications to be implemented.

One aim of the invention is to overcome at least one of the problems posed by the prior art.

According to a first aspect of the invention, what is proposed is a matrix light source comprising an integrated circuit and a matrix array of electroluminescent semiconductor element-based elementary light sources. The integrated circuit comprises at least one electronic circuit intended to drive the supply of electric power to the elementary light sources, and a reception area having a substrate and intended to receive said matrix array. The matrix light source is noteworthy in that the integrated circuit comprises at least one part, including a part of the reception area and the electronic circuit, that is repeated at least once along a main axis.

The distance between the matrix components may preferably be less than 10 μm.

The substrate of the reception area may preferably comprise at least part of the electronic circuit.

The elementary light sources may preferably be electrically connected to the electronic circuit by connections that are vertical with respect to the extent of the reception area.

The matrix array of elementary light sources may preferably consist of at least two separate matrix components.

The matrix light source may preferably extend along a main axis.

The integrated circuit may preferably comprise at least one connection area adjacent to the reception area, the connection area being intended to connect the electronic circuit to at least one external component.

The connection area may preferably extend along at least one edge of the integrated circuit that follows the main axis. Said edge may preferably be parallel to the main axis.

The connection area may preferably comprise means for connection to an electricity source, the connection means being formed by a metal layer. This preferably involves a metal with good electrical conduction, for example copper Cu, aluminum Al, gold Au or silver Ag.

The connection area may preferably comprise a plurality of connection pads, the respective areas of which depend on the signals and/or the electric current intensities that they are intended to transmit. The connection means may preferably comprise said connection pads.

The connection area may preferably comprise a connection pad, possibly distributed over multiple interconnected parts of the connection area, the area of which is capable of transmitting a current with an intensity of at least 15 A.

The connection area may preferably comprise at least one through-aperture.

The light source may preferably consist of matrix components of similar dimensions and comprising an identical number of elementary light sources.

The light source may preferably comprise at least one matrix component of dimensions 7×11, 14×11, 28×22 or 44×28 elementary light sources. The light source may preferably comprise a combination of these matrix components.

According to another aspect of the invention, what is proposed is a lighting module for a motor vehicle. The module comprises a heat sink element, a printed circuit board and a matrix light source. The module is noteworthy in that the matrix light source is in accordance with one aspect of the invention.

The substrate of the integrated circuit may preferably be in thermal contact with the heat sink element. The matrix light source may preferably be electrically connected to the printed circuit board by way of at least one bridging connection.

The integrated circuit may preferably comprise an Si substrate. The integrated circuit is preferably soldered or adhesively bonded to the matrix array of elementary light sources, for example to a common substrate supporting the elementary light sources. The integrated circuit is preferably in mechanical contact, for example via fastening means, and in electrical contact with a bottom layer of the elementary light sources.

The pixelated light source, or equivalently, the matrix light source, or else one of the matrix components of the matrix light source, may preferably comprise at least one matrix array of electroluminescent elements—the elementary light sources, also called monolithic array, being arranged in at least two columns by at least two rows. The electroluminescent source preferably comprises at least one monolithic matrix array of electroluminescent elements, also called a monolithic matrix array.

In a monolithic matrix array, the electroluminescent elements are grown from a common substrate and are electrically connected so as to be able to be activated selectively, individually or by subset of electroluminescent elements. Each electroluminescent element or group of electroluminescent elements may thus form one of the elementary emitters of said pixelated light source that is able to emit light when its or their material is supplied with electricity.

Various arrangements of electroluminescent elements may meet this definition of a monolithic matrix array, provided that the electroluminescent elements have one of their main dimensions of elongation substantially perpendicular to a common substrate and that the spacing between the elementary emitters, formed by one or more electroluminescent elements grouped together electrically, is small in comparison with the spacings that are imposed in known arrangements of flat square chips soldered to a printed circuit board.

The substrate of the monolithic component may be made predominantly of semiconductor material. The substrate may comprise one or more further materials, for example non-semiconductor materials. These electroluminescent elements, of submillimeter dimensions, are for example arranged so as to project from the substrate so as to form rods of hexagonal cross section. The electroluminescent rods originate on a first face of a substrate. Each electroluminescent rod, formed in this case using gallium nitride (GaN), extends perpendicularly, or substantially perpendicularly, projecting from the substrate, in this case produced from silicon, with other materials, such as silicon carbide, being able to be used without departing from the context of the invention. By way of example, the light-emitting rods could be produced from an alloy of aluminum nitride and of gallium nitride (AlGaN), or from an aluminum, indium and gallium phosphide (AlInGaP). Each electroluminescent rod extends along an axis of elongation defining its height, the base of each rod being arranged in a plane of the upper face of the substrate.

The electroluminescent rods of one and the same monolithic matrix array advantageously have the same shape and the same dimensions. They are each delimited by an end face and by a circumferential wall that extends along the axis of elongation of the rod. When the electroluminescent rods are doped and subjected to polarization, the resulting light at the output of the semiconductor source is emitted mainly from the circumferential wall, it being understood that light rays may also exit from the end face. The result of this is that each electroluminescent rod acts as a single light-emitting diode and that the luminance of this source is improved firstly by the density of the electroluminescent rods that are present and secondly by the size of the lighting surface defined by the circumferential wall and that therefore extends over the entire perimeter and the entire height of the rod. The height of a rod may be between 2 and 10 μm, preferably 8 μm. The largest dimension of the end face of a rod is less than 2 μm, preferably less than or equal to 1 μm.

It is understood that, when forming the electroluminescent rods, the height may be modified from one area of the pixelated light source to another in such a way as to boost the luminance of the corresponding area when the average height of the rods forming it is increased. Thus, a group of electroluminescent rods may have a height, or heights, that are different from another group of electroluminescent rods, these two groups forming the same semiconductor light source comprising electroluminescent rods of submillimeter dimensions. The shape of the electroluminescent rods may also vary from one monolithic matrix array to another, in particular over the cross section of the rods and over the shape of the end face. The rods have a generally cylindrical shape, and they may in particular have a polygonal and more particularly hexagonal cross section. It is understood that it is important, for light to be able to be emitted through the circumferential wall, that the latter has a polygonal or circular shape.

Moreover, the end face may have a shape that is substantially planar and perpendicular to the circumferential wall, such that it extends substantially parallel to the upper face of the substrate, or else it may have a shape that is curved or pointed at its center, so as to increase the directions in which the light exiting from this end face is emitted.

The electroluminescent rods may preferably be arranged in a two-dimensional matrix array. This arrangement could be such that the rods are arranged in a quincunx. Generally speaking, the rods are arranged at regular intervals on the substrate and the distance separating two immediately adjacent electroluminescent rods, in each of the dimensions of the matrix array, should be at least equal to 2 μm, preferably between 3 μm and 10 μm, such that the light emitted through the circumferential wall of each rod is able to exit from the matrix array of electroluminescent rods. Provision is furthermore made for these separating distances, measured between two axes of elongation of adjacent rods, not to be greater than 100 μm.

As an alternative, the monolithic matrix array may comprise electroluminescent elements formed by layers of epitaxial electroluminescent elements, in particular a first, n-doped layer of GaN and a second, p-doped layer of GaN, on a single substrate, for example made of sapphire or of silicon carbide, and which is sliced (by grinding and/or ablation) to form a plurality of elementary emitters respectively originating from one and the same substrate. The result of such a design is a plurality of electroluminescent blocks all originating from one and the same substrate and electrically connected so as to be able to be activated selectively from one another.

In one exemplary embodiment according to this other embodiment, the substrate of the monolithic matrix array may have a thickness of between 5 μm and 800 μm, in particular equal to 200 μm; each block may have a length and a width, each being between 50 μm and 500 μm, preferably between 100 μm and 200 μm. In one variant, the length and the width are equal. The height of each block is less than 500 μm, preferably less than 300 μm. Finally, the exit surface of each block may be formed via the substrate on the side opposite the epitaxy. The separating distance between two elementary emitters. The distance between each contiguous elementary emitter may be less than 1 mm, in particular less than 500 μm, and is preferably less than 200 μm.

As an alternative, both with electroluminescent rods extending respectively projecting from one and the same substrate, as described above, and with electroluminescent blocks obtained by slicing electroluminescent layers superimposed on one and the same substrate, the monolithic matrix array may furthermore comprise a layer of a polymer material in which the electroluminescent elements are at least partially embedded. The layer may thus extend over the entire extent of the substrate, or only around a given group of electroluminescent elements. The polymer material, which may in particular be silicone-based, creates a protective layer that makes it possible to protect the electroluminescent elements without impairing the diffusion of the light rays. Furthermore, it is possible to integrate, into this layer of polymer material, wavelength conversion means, for example luminophores, that are able to absorb at least some of the rays emitted by one of the elements and to convert at least some of said absorbed excitation light into an emission light having a wavelength that is different from that of the excitation light. Provision may be made without distinction for the luminophores to be embedded in the mass of the polymer material, or else to be arranged on the surface of the layer of this polymer material.

The pixelated light source may furthermore comprise a coating of reflective material to deflect the light rays to the exit surfaces of the light source.

The electroluminescent elements of submillimeter dimensions define a given exit surface in a plane substantially parallel to the substrate. It will be understood that the shape of this exit surface is defined as a function of the number and the arrangement of the electroluminescent elements that form it. It is thus possible to define a substantially rectangular shape of the emission surface, it being understood that the latter may vary and adopt any shape without departing from the context of the invention.

By using the measures proposed by the present invention, it becomes possible to propose an adjustable architecture of matrix light sources. On the one hand, according to some embodiments of the invention, a modular architecture of the integrated circuit that houses one or more elementary electroluminescent light source-based matrix components makes it possible to implement multiple sizes, by repeating the structure of an integrated circuit module in full along a main axis of the matrix source. On the other hand, the matrix light source according to some aspects of the invention makes it possible to match the size of the integrated circuit to the size of the available matrix component or components. Since the matrix light source allows a plurality of matrix components to be installed therein, a large matrix light source may be produced using two or more matrix components of small size, the lighting characteristics of which are similar and the homogeneous production of which is better harnessed than that of larger matrix components. The optical homogeneity of the matrix source is thereby improved as a result. In addition, since all of the matrix components share the same substrate, which is preferably fastened directly to a heat sink element, the dissipation of heat across the entire matrix source is homogenized.

Other features and advantages of the present invention will be better understood with the aid of the description of the examples and of the drawings, in which:

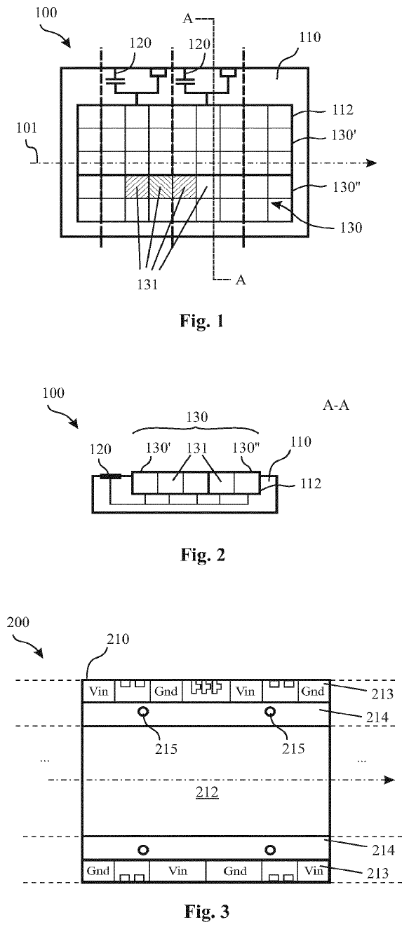

FIG. 1 schematically shows a plan view of a matrix light source according to one preferred embodiment of the invention;

FIG. 2 schematically shows a cross section of a matrix light source according to one preferred embodiment of the invention;

FIG. 3 schematically shows a plan view of an integrated circuit of a matrix light source according to one preferred embodiment of the invention.

Unless specified otherwise, technical features that are described in detail for one given embodiment may be combined with the technical features that are described in the context of other embodiments described by way of example and without limitation. Similar reference numerals will be used to describe similar concepts across various embodiments of the invention. For example, the references 100 and 200 denote two embodiments of a matrix light source according to the invention.

The description focuses on the elements and components of a motor vehicle that are linked directly to the aspects of the invention. Other well-known elements will not be described in detail or mentioned. For the example of a lighting module in accordance with aspects of the invention, this involves, for example and without limitation, optical elements such as optical lenses or reflectors, or various supports for keeping components in their intended locations.

The illustration in FIG. 1 shows a pixelated light source or matrix light source 100 according to one preferred embodiment of the invention. The light source 100 comprises an integrated circuit 110 as well as a matrix array 130 that comprises a plurality of electroluminescent element-based elementary light sources 131. The integrated circuit is preferably produced using the well-known CMOS (“complementary metal oxide semiconductor”) technology, and it comprises in particular at least one electronic circuit 120 intended to drive the supply of electric power to the elementary light sources 131. Without limitation, the electronic circuit 120 may for example comprise means for connection to an electricity source external to the matrix source, such as a battery or a converter capable of supplying an electric current of an intensity suitable for supplying power to the elementary light sources. The electronic circuit may furthermore comprise switch elements, formed for example by way of MOSFET field-effect transistors, which make it possible to selectively supply power to the elementary sources 131 individually or in groups, in accordance with received commands. To this end, the electronic circuit may comprise a circuit for receiving such a command, the command being generated by an entity external to the matrix source.

The integrated circuit 110 comprises a reception area 112 intended to house the matrix array 130. The reception area is preferably rectangular. The geometry of the integrated circuit 110 is particular in that at least part of its structure, including the reception area and the electronic circuit that is integrated therein, is repeated at least once along a main axis 101.

In the illustration in FIG. 1, the part of the integrated circuit that is repeated is located between two dashed vertical lines. Each repetition of this structure is implemented using an identical mask during production of the integrated circuit through CMOS technology. The invention is obviously not limited to a single repetition of the structure. Depending on the size of the matrix array 130 that will be housed by the integrated circuit, the same mask may be used along the main axis 101 so as to extend the integrated circuit, in order to increase the number of addressable pixels of the matrix array 130. Since the electronic circuit 120 of each repeated part comprises the electronic components required to supply power to and control the elementary light sources 131 that are housed by the corresponding repeated part of the reception area 112, the architecture is adjustable in terms of size along the axis 101.

In the example shown, two matrix components 130′ and 130″ are used to form the matrix array 130. The matrix components are for example produced independently of one another.

FIG. 2 shows a cross section along the axis A-A indicated in FIG. 1. It shows the reception area 112, which is preferably formed by a rectangular recess in the substrate, generally made of silicon, Si, of the integrated circuit. This geometrical characteristic does not however limit the invention. The electronic circuit 120 comprises connections at the reception area 112, which make it possible in particular to make electrical contact with each of the elementary light sources 131 individually via their lower face, which is in contact with the substrate of the reception area 112. The vertical connection thus produced by elements embedded in the integrated circuit makes it possible to dispense with individual wiring for the elementary light sources.

The matrix light source 100 comprises a matrix array 130 of electroluminescent semiconductor element-based elementary light sources 131 and may comprise a common substrate, not illustrated, in mechanical and electrical contact with and functionally connected to the integrated circuit 120. The elementary light sources are typically light-emitting diodes (LEDs).

The matrix light source 100 preferably, but without limitation, comprises a monolithic matrix component, in which the semiconductor layers of the elementary light sources 131 are for example arranged on the common substrate. The matrix array of elementary light sources 130 preferably comprises a parallel assembly of a plurality of branches, each branch comprising electroluminescent semiconductor light sources 131.

By way of example and without limitation, the matrix array of elementary light sources 130 comprises, along the thickness of the substrate and starting at the end opposite the location of the elementary sources 310, a first electrically conductive layer deposited on an electrically insulating substrate. This is followed by an n-doped semiconductor layer whose thickness is between 0.1 and 2 μm. The following layer is the active quantum well layer having a thickness of around 30 nm, followed by an electron-blocking layer, and finally a p-doped semiconductor layer, the latter having a thickness of around 300 nm. Preferably, the first layer is an (Al)GaN:Si layer, the second layer is an n-GaN:Si layer, and the active layer comprises quantum wells made of InGaN alternating with barriers made of GaN. The blocking layer is preferably made of AlGaN:Mg and the p-doped layer is preferably made of p-GaN:Mg.

In order to achieve elementary light sources 131 having semiconductor layers having homogeneous thicknesses, the monolithic component is preferably manufactured by depositing the layers homogeneously and uniformly over at least part of the surface of the substrate so as to cover it. The layers are deposited for example using a metal oxide chemical vapor deposition (MOCVD) method. Such methods and reactors for implementing them are known for depositing semiconductor layers on a substrate, for example from patent documents WO 2010/072380 A1 or WO 01/46498 A1. Details on their implementation will therefore not be described in the context of the present invention. The layers thus formed are then pixelated. By way of example and without limitation, the layers are removed using known lithographic methods and by etching at the sites that subsequently correspond to the spaces between the elementary light sources 131 on the substrate. A plurality of several tens or hundreds or thousands of pixels 131 having a surface area smaller than one square millimeter for each individual pixel, and having a total surface area greater than 2 square millimeters, having semiconductor layers with homogeneous thicknesses, and therefore having homogeneous and high internal series resistances, are thus able to be produced on the substrate of a matrix light source. Generally speaking, the more the size of each LED pixel decreases, the more its series resistance increases, and the more this pixel is able to be driven by a voltage source. As an alternative, the substrate comprising the epitaxial layers covering at least part of the surface of the substrate is sawn or divided into elementary light sources, each of the elementary light sources having similar characteristics in terms of their internal series resistance.

The invention also relates to types of semiconductor element-based elementary light sources involving other configurations of semiconductor layers. In particular the substrates, the semiconductor materials of the layers, the arrangement of the layers, their thicknesses and any vias between the layers may be different from the example that has just been described.

The integrated circuit 110 is preferably soldered to the lower face of the matrix array, which houses the elementary light sources on its upper face, so as to establish mechanical and electrical contact with the substrate and the elementary light sources. Using an integrated circuit 110 in mechanical and electrical contact with the substrate on which the elementary light sources reside makes it possible to dispense with wired connections, the number of which would be at least equal to the number of pixels of the matrix light source. Preferably, a power supply circuit may be integrated into the substrate when the monolithic component is manufactured.

The illustration in FIG. 3 shows a pixelated light source or matrix light source 200 according to another preferred embodiment of the invention. The light source 200 comprises an integrated circuit 210 as well as a matrix array, not illustrated, that consists of a plurality of electroluminescent element-based elementary light sources. The integrated circuit is preferably produced using the well-known CMOS (“complementary metal oxide semiconductor”) technology, and it comprises in particular at least one electronic circuit intended to drive the supply of electric power to the elementary light sources. At least one connection area 213, 214 of the integrated circuit makes it possible to connect the electronic circuit to other external components. The connection area 213, 214 extends along an edge that follows the main axis of the integrated circuit. In the example in FIG. 2, connection areas 213, 214 are provided on the two opposite edges that follow the main axis.

The part 213 of the connection area makes it possible in particular to connect the matrix light source 200 to an external electricity source. The Si substrate of the integrated circuit is preferably soldered directly or adhesively bonded by way of a thermal adhesive to a heat sink element, for example consisting of an aluminum block. The connection area 213 makes it possible to connect the electronic circuits installed in the integrated circuit 210 to various electrical potentials Vin, Gnd, as well as preferably digital logic control signals via a direct bridging link to an external printed circuit board that houses the corresponding electrical sources. To this end, the connection area comprises dedicated connection pads. The pads Vin, Gnd may for example have a maximum area that makes it possible to transmit an electric current of high intensity, for example at least 15 A. Other connection pads provided for the transmission of digital commands may have smaller areas. The bridging links may therefore also be formed by way of wires or ribbons having suitable dimensions. Wires with a diameter of 50 or 125 μm may be used for digital signal transmission. For example, ribbons measuring 400×100 μm or a wire with a diameter of 200 μm may be used to transmit an intense electric current. The connection area may preferably comprise four connections capable of transmitting a high-intensity electric current, distributed over two edges of the integrated circuit.

The direct thermal link between the Si substrate of an integrated circuit and a heat sink element, as well as the direct bridging link to an external circuit, may also be applied to other types of integrated circuit that do not comprise the other features in accordance with the aspects of the present invention.

A bridging connection using the technique known as “wire bonding” or “ribbon bonding” or even “copper clip” is used for this purpose. This type of connection allows the transmission of high electric currents and the rapid transmission of logic signals. The connection comprises a connection pad on the printed circuit board and in the connection area 213 of the integrated circuit 210, and an electrically conductive wire that connects the two connection pads. Each connection pad is electrically connected to the electronic circuit of the respective printed circuit board/integrated circuit. The electrically conductive wire is soldered between the two connection pads, for example by ultrasonic soldering. The material of the wire is aluminum, gold, copper or silver, while its diameter is between 75 μm and 250 μm. According to one preferred embodiment, the connection pads comprise, at least on their surface, a layer of the same material of which the wire consists in order to facilitate the soldering step.

The connection areas 213, 214 preferably comprise a metal layer, the dimensions of which are suitable for conducting high-intensity electric currents, for example of more than 15 A. Specifically, the matrix source should be capable of managing intense electric currents, given the large number of elementary light sources that it may house.

The integrated circuit 210 furthermore comprises a reception area 212 adjacent to the connection area 213, 214 and intended to house the matrix array of elementary light sources. The reception area is preferably rectangular. The geometry of the integrated circuit 210 is particular in that at least part of its structure, including the reception area and the electronic circuit that is integrated therein, is repeated at least once along a main axis. In the illustration in FIG. 3, only the part of the integrated circuit that is repeated is shown, the repetitions not being illustrated. This structure is implemented using an identical mask during production of the integrated circuit through CMOS technology. The repetitions are advantageously implemented without any offset between the repeated structures, but some variants may be implemented with an offset, as long as the matrix function is not altered. Since the size of the integrated circuit 210 may become large depending on the number of repetitions of the modular pattern of the integrated circuit along the main axis, apertures, preferably through-apertures, or holes 215 may be provided at the connection area 213, 214 of the integrated circuit 210, in order to reduce the mechanical stresses therein. This measure in particular reduces the risk of the connection pads used in the bridging links becoming unstuck due to mechanical stresses in the substrate of the integrated circuit 210.

It goes without saying that the integrated circuit may comprise other electronic circuits and/or memory elements used for other functions in connection with the matrix light source and/or with the elementary light sources. This includes but is not limited to circuits for detecting a short circuit or an open circuit fault with an elementary light source.

The scope of protection is defined by the claims.

1. A matrix light source comprising an integrated circuit and a matrix array of electroluminescent semiconductor element-based elementary light sources, wherein the integrated circuit comprises at least one electronic circuit intended to drive the supply of electric power to the elementary light sources, and a reception area having a substrate and intended to receive said matrix array, characterized in that the integrated circuit comprises at least one part, including a part of the reception area and the electronic circuit, that is repeated at least once along a main axis.

2. The light source as claimed in claim 1, wherein the substrate of the reception area comprises at least part of the electronic circuit.

3. The light source as claimed in claim 2, wherein the elementary light sources are electrically connected to the electronic circuit by connections that are vertical with respect to the extent of the reception area.

4. The light source as claimed in claim 1, wherein the matrix array of elementary light sources consists of at least two separate matrix components.

5. The light source as claimed in claim 1, wherein the integrated circuit comprises at least one connection area adjacent to the reception area), the connection area being intended to connect the electronic circuit to at least one external component.

6. The light source as claimed in claim 5, wherein the connection area extends along at least one edge of the integrated circuit that follows the main axis.

7. The light source as claimed in claim 5, wherein the connection area comprises at least one through-aperture.

8. The light source as claimed in claim 5, wherein the connection area comprises a plurality of connection pads, the respective areas of which depend on the signals and/or the electric current intensities that they are intended to transmit.

9. The light source as claimed in claim 5, wherein the connection area comprises means for connection to an electricity source, the connection means being formed by a metal layer.

10. A lighting module for a motor vehicle, the module comprising a heat sink element, a printed circuit board and a matrix light source, wherein the matrix light source is as claimed in claim 1.

11. The lighting module as claimed in claim 10, wherein the substrate of the integrated circuit is in thermal contact with the heat sink element.

12. The lighting module as claimed in claim 10, wherein the matrix light source is electrically connected to the printed circuit board by way of at least one bridging connection.

13. The light source as claimed in claim 2, wherein the matrix array of elementary light sources consists of at least two separate matrix components.

14. The light source as claimed in claim 2, wherein the integrated circuit comprises at least one connection area adjacent to the reception area, the connection area being intended to connect the electronic circuit to at least one external component.

15. The light source as claimed in claim 6, wherein the connection area comprises at least one through-aperture.

16. The light source as claimed in claim 6, wherein the connection area comprises a plurality of connection pads, the respective areas of which depend on the signals and/or the electric current intensities that they are intended to transmit.

17. The light source as claimed in claim 6, wherein the connection area comprises means for connection to an electricity source, the connection means being formed by a metal layer.

18. A lighting module for a motor vehicle, the module comprising a heat sink element, a printed circuit board and a matrix light source, wherein the matrix light source is as claimed in claim 2.

19. The lighting module as claimed in claim 11, wherein the matrix light source is electrically connected to the printed circuit board by way of at least one bridging connection.

20. The light source as claimed in claim 3, wherein the matrix array of elementary light sources consists of at least two separate matrix components.
